(19) United States
(12) Patent Application Publication
(10) Pub. No.: US 2010/0148228 A1
(43) Pub. Date: Jun. 17, 2010

(54) SEMICONDUCTOR AND MANUFACTURING METHOD OF THE SAME

(75) Inventors: Young Man Cho, Icheon-si (KR); Won Sun Seo, Gangwon-do (KR)

Correspondence Address: AMPACC Law Group, 3500 188th Street S.W., Suite 103, Lynnwood, WA, 98037, US

(73) Assignee: Hynix Semiconductor Inc., Icheon-si (KR)

(21) Appl. No.: 12/495,599

(22) Filed: Jun. 30, 2009

(30) Foreign Application Priority Data
Dec. 11, 2008 (KR) 10-2008-0126006

(51) Int. Cl. H01L 29/78; H01L 21/768

(52) U.S. Cl. 257/288; 438/674; 257/E29.255; 257/E21.585

(57) ABSTRACT

A semiconductor device includes a gate formed on a semiconductor substrate. A first junction region is formed on a first side of the gate and a second junction region formed on a second side of the gate. A bit line is formed over the gate to be electrically coupled with the first junction region. A first metal plug is formed electrically coupling the second junction region. A bit line contact plug is provided between the first junction region and the bit line, and electrically couples the first junction region and the bit line. A second metal plug is formed over the first metal plug and electrically couples the first metal plug. The junction region of a gate in a core or peripheral region is connected to the metal line using a metal plug so that bit lines formed in the core and peripheral area can have a pattern similar to that formed in a cell region.

### CROSS-REFERENCE TO RELATED APPLICATION

The priority of Korean patent application No. 10-2008-0126006 filed on Dec. 11, 2008, the disclosure of which is hereby incorporated in its entirety by reference, is claimed.

### BACKGROUND OF THE INVENTION

The present invention relates to a semiconductor device, and more particularly, to a semiconductor device capable of minimizing defects caused in the course of patterning a bit line in a core region and a peripheral region (in particular, in a core region), and a manufacturing method thereof.

Generally, a semiconductor device such as a DRAM includes a memory cell array area (or a memory cell array region) and a core and peripheral area (or a core and peripheral region or a core region).

The memory cell array area is an area in which a plurality of word lines, a plurality of bit lines, and a plurality of memory cells are formed. The memory cells are arranged at a point where the word line and the bit line intersect each other.

The core and peripheral area is an area in which circuits for operating and controlling the memory cells are formed. In the core region, a bit line sense amplifier (BLSA) connected to the bit line and a sub word line drive (SWD) connected to the word line are formed.

Recently, as the design rule for a semiconductor device becomes smaller, the line/space width of the bit line becomes smaller in the core and peripheral area as well as in the cell array region.

Particularly, since the bit line patterns formed in the core region are not uniform in size and shape, unlike the bit line patterns formed in the cell region, defects tend to easily occur in the course of patterning the bit line in the core region.

FIG. 1 shows patterns formed in the conventional core region.

A gate insulating layer (not shown) is formed over a semiconductor substrate 10. The semiconductor substrate 10 includes a field isolation region and an active region. A gate 12 is formed on the gate insulating layer.

Impurity ions are implanted into the semiconductor substrate 10 between the gates 12 to form a source/drain region (not shown), so that a transistor is formed. The transistor can form a sense amplifier.

A bit line 16 is formed so as to be electrically coupled with the source/drain region through a bit line contact plug 14.

A metal line 20 is formed along a direction perpendicular to the bit line 16, and the metal line 20 is electrically coupled with the bit line 16 through a metal line contact plug 18.

The size or shape of the bit line 16 formed in the core region varies depending on the location of the bit line, while the bit lines (not shown) in the cell array region are formed in the same size and in the same shape regardless of their location. Thus, the bit line pattern in the core region forms an irregular line pattern with irregular sides or forms an island pattern at the location over which the metal line contact plug 18 is passing by. Accordingly, the line width of bit lines is not uniform and the distance between the neighboring bit lines (space width) is not uniform.

This is because, as shown in FIG. 1, when the metal line 20 is connected to the source/drain region through the bit line 16, a corresponding bit line region has to be formed with an island type.

Since the bit line patterns in the core region are formed in irregular forms, patterning defects frequently occur in the course of bit line formation.

Furthermore, in order to implement below-40 nm technology, SPT (Spacer Patterning Technology) should be employed. However, SPT is hard to apply for forming an irregular pattern.

### BRIEF SUMMARY OF THE INVENTION

Various embodiments of the invention are directed to prevent the inferiority of bit line patterning in a core region in such a manner that bit lines formed in the core region are also capable of having a pattern of regular form like a cell region by improving the manufacturing process of a semiconductor device.

According to the present invention, a semiconductor device comprises: a transistor which is formed on a semiconductor substrate; a bit line which is formed in the upper portion of the transistor; a bit line contact which connects a first junction region of the transistor to the bit line; and a metal plug which connects a second junction region of the transistor to a metal line or a metal line contact.

Preferably, the transistor is a transistor which is formed in the core and peripheral area.

Preferably, the second junction region is a source junction region or a gate junction region.

Preferably, the upper portion of the metal plug is overlapped with a part or the whole of the upper portion of adjacent bit line.

Preferably, the bit line has a constant gap with an adjacent bit line.

Preferably, the bit line is formed with a stripe type.

Preferably, the metal plug is formed with one of the tungsten W, the aluminum Al, the copper Cu and an alloy of those metals.

Preferably, the metal plug comprises: a first metal plug which is formed in the upper portion of the second junction region so as to be connected to the second junction region; and a second metal plug which connects the first metal plug to the metal line or the metal line contact.

Preferably, the first metal plug is formed with a material which is identical with the bit line contact.

Preferably, the second metal plug is formed with one of the tungsten W, the aluminum Al, the copper Cu and an alloy of those metals.

Preferably, the semiconductor device further comprises a silicide film formed in a contact surface of the metal plug and the second junction region.

Preferably, the silicide film is one of the TiSi2 film, the TiNSi2 film and the CoSi2 film.

According to a first embodiment of the present invention, a method of manufacturing a semiconductor device comprises: forming a first interlayer insulating layer including a transistor on a semiconductor substrate; forming a bit line contact connected to a first junction region of the transistor within the first interlayer insulating layer; forming a second interlayer insulating layer including a bit line on the upper portion of the first interlayer insulating layer; forming a metal plug which is connected to a second junction region of the transistor while passing through the first interlayer insulating layer and the second interlayer insulating layer; and forming a metal line contact connected to the metal plug.

Preferably, forming a metal plug comprises: forming a contact hole which exposes the second junction region of the transistor by successively etching the second interlayer insulating layer and the first interlayer insulating layer; forming a silicide film on the lower portion of the contact hole; and forming a metal layer for plug in the upper portion of the silicide film so that the contact hole be filled in.

Preferably, the contact hole is formed by dry etching the second interlayer insulating layer and the first interlayer insulating layer.

Preferably, in forming a contact hole, the SAC (Self Align Contact) etching method utilizing an etching selectivity of bit line hard mask film and bit line spacer is used.

Preferably, forming a silicide film comprises: forming an amorphous metal film on the surface of the contact hole; and transforming the amorphous metal film into the silicide film by performing a thermal process.

Preferably, forming a silicide film comprises: forming an amorphous metal film on the surface of the contact hole; selectively etching the amorphous metal film so that the amorphous metal film be left behind only in the lower portion of the contact hole; and transforming the left behind amorphous metal film into the silicide film by performing a thermal process.

According to a second embodiment of the present invention, a method of manufacturing a semiconductor device comprises: forming a first interlayer insulating layer including a transistor on a semiconductor substrate; forming a bit line contact connected to a first junction region of the transistor and a first metal plug contact connected to a second junction region of the transistor within the first interlayer insulating layer; forming a second interlayer insulating layer including a bit line on the upper portion of the first interlayer insulating layer; forming a second metal plug connected to the first metal plug by etching the second interlayer insulating layer; and forming a metal line contact connected to the second metal plug.

Preferably, in etching the second interlayer insulating layer, the SAC (Self Align Contact) etching method utilizing an etching selectivity of bit line hard mask film and bit line spacer is used.

The bit line of the core and peripheral area of the present invention can be formed with a stripe type like the cell region so that the inferiority of bit line patterning can be prevented. Furthermore, as the bit line is formed with a stripe type, the SPT process can be applied when forming the bit line of the core and peripheral area.

### BRIEF DESCRIPTION OF THE DRAWINGS

FIG. 1 is a drawing illustrating patterns formed in a conventional core region;

FIG. 2 is a plan view illustrating patterns formed in a core region of a semiconductor device according to an embodiment of the present invention;

FIG. 3 is a cross-sectional view taken along the line A-A′ of FIG. 2;

FIGS. 4a to 4d are cross-sectional views for illustrating the manufacturing method of a semiconductor device having the structure of FIG. 3;

FIG. 5 is a cross-sectional view illustrating a configuration of a semiconductor device according to a second embodiment of the present invention; and

FIGS. 6a to 6c are cross-sectional views for illustrating the manufacturing method of a semiconductor device having the structure of FIG. 5.

FIG. 7 shows cross-sectional views of semiconductor devices according to a third and a fourth embodiment of the present invention.

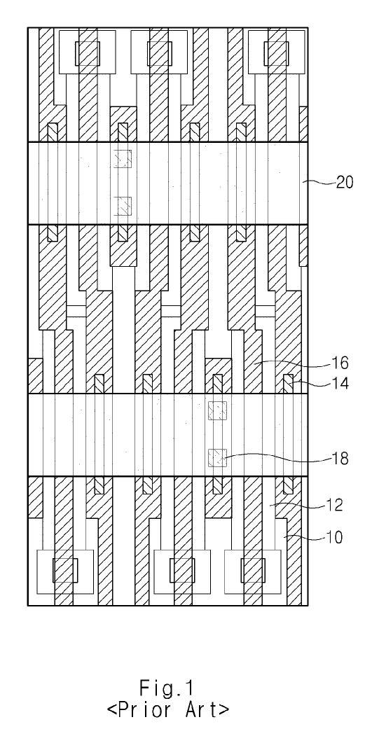

### DESCRIPTION OF EMBODIMENTS

The present invention is described with reference to the accompanying drawings in detail. The same reference numerals are used throughout the drawings to refer to the same or like parts. Detailed description on well-known functions and structures may be omitted.

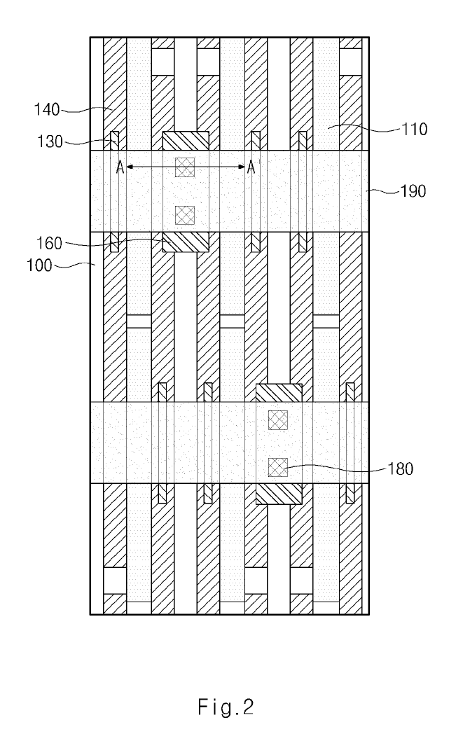

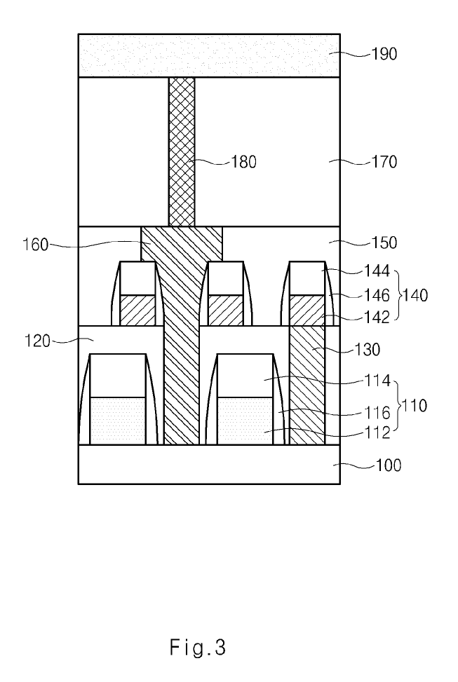

FIG. 2 is a plan view illustrating patterns formed in a core region of a semiconductor device according to the present invention, FIG. 3 is a cross-sectional diagram taken along line A-A′ of FIG. 2.

A gate insulating layer (not shown) is formed on a semiconductor substrate 100 in which a field isolation region and an active region are formed and a gate 110 is formed on the gate insulating layer. The gate includes a gate electrode 112 formed on the gate insulating layer, a gate hard mask film 114 formed on the gate electrode 112, and a gate spacer 116 formed on the side wall of the gate electrode 112 and the gate hard mask film 114.

Impurity ions are implanted into the semiconductor substrate 100 between the gates 110 to form a source/drain region (not shown). The transistor can form a sense amplifier. A first interlayer insulating layer 120 is formed on the gate 110. A bit line 140 is formed on the first interlayer insulating layer 120. The first interlayer insulating layer 120 is formed of an oxide layer. The oxide layer can be made of a HDP (high density plasma) oxide layer, a PSG (phosphosilicate glass) oxide layer, a PE-TEOS (plasma enhanced tetra-ethoxy silicate) layer or a stacked combination of them. The bit line 140 is formed on the interlayer insulating layer 120. An interlayer insulating layer 150 is formed over the interlayer insulating layer 120 and the bit line 140. The bit line 140 includes a bit line electrode 142, a bit line hard mask film 144 formed on the bit line electrode 142, and a bit line spacer 146 formed on the side wall of the bit line hard mask film 144 and the bit line electrode 142. Particularly, in the present embodiment, the bit line 140 formed in the core region is formed of a stripe pattern whose width and space are substantially uniform as shown in FIG. 3. As described above, in order to provide the bit line 140 with a substantially uniform stripe pattern, the source junction region is connected to the metal line contact plug 180 through the metal plug 160. The metal plug 160 can be formed of tungsten (W), aluminum (Al), copper (Cu) or an alloy of these metals.

The upper portion of the metal plug 160, as shown in FIG. 3, is broadly formed so that an overlap margin between the metal plug 160 and the metal line contact plug 180 can be sufficiently secured. On the junction between the metal plug 160 and the source region, a silicide film (not shown) can be formed so as to reduce contact resistance. TiSi2 film, TiNSi2 film, or CoSi2 film can be used as the silicide film.

An interlayer insulating layer 170 is formed on the interlayer insulating layer 150 and the metal plug 160. The metal line contact plug 180 is defined within the insulating layer 170. A metal line 190 connected to the metal line contact 180 is formed on the interlayer insulating layer 170.

As described, in the present invention, since the source junction region and the metal line 190 is connected not by the bit line in the core region but by the metal plug 160, the bit line 140 in the core region can be uniformly formed in a stripe pattern shape.

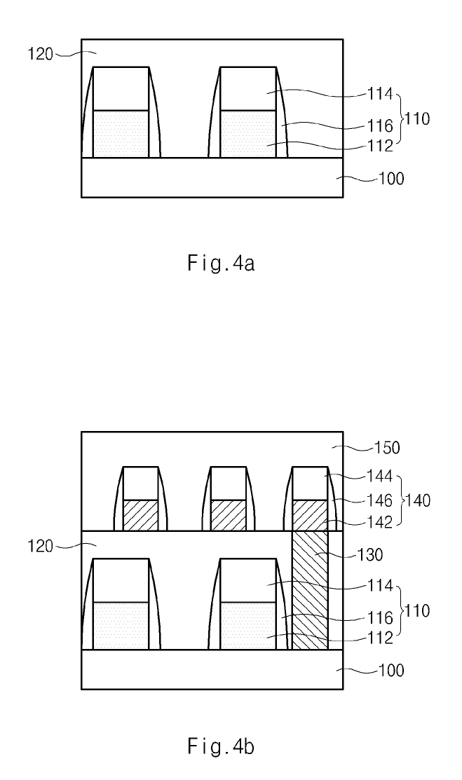

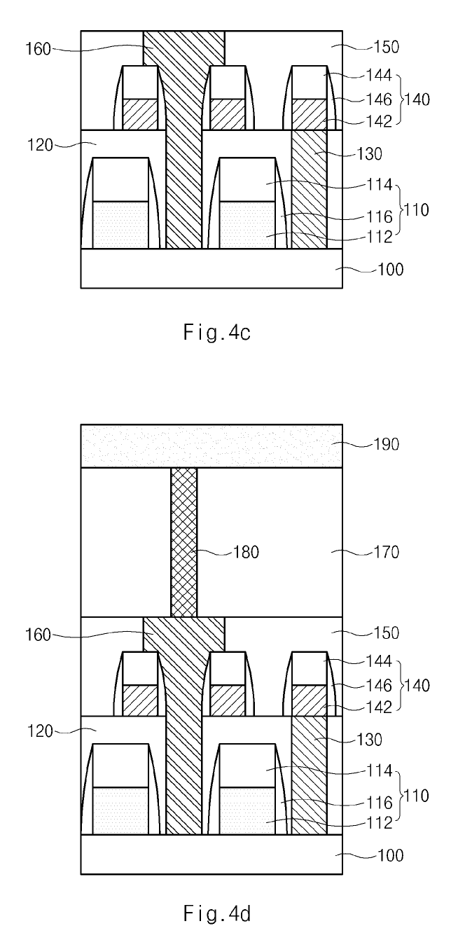

FIGS. 4a to 4d are cross-sectional diagrams for illustrating a manufacturing method of a semiconductor device shown in FIG. 3.

Referring to FIG. 4a, for example, a gate insulating layer (not shown) is formed on the semiconductor substrate 100 in a sense amplifier (SA) region. Then, a metal layer including a gate electrode and a hard mask film are subsequently formed on the gate insulating layer. Tungsten silicide can be used for the gate electrode, and a nitride film can be used for the hard mask film.

The metal layer and the hard mask film are selectively etched using a mask defining a gate to form a stacked structure of the gate electrode 112 and the gate hard mask film 114. Impurity ions are implanted into the semiconductor substrate 100 of both sides of the gate electrode 112 to form a source region and a drain region, so that a transistor for a sense amplifier is formed.

Then, a nitride film (not shown) for the spacer is formed on the stacked structure of the gate electrode 112 and the gate hard mask film 114 and the semiconductor substrate 100. The nitride film is then subjected to an etch-back process, so that the spacer 116 is formed on the side wall of the stack structure of the gate electrode 112 and the gate hard mask film 114.

An insulating layer is formed on the gate 110 and the semiconductor substrate 100 and then planarized to form the interlayer insulating layer 120. The interlayer insulating layer 120 can be formed of a HDP (high density plasma) oxide layer, a PSG (phosphosilicate glass) oxide layer, a PE-TEOS (plasma enhanced tetra-ethoxy silicate) layer or a stacked combination of those layers.

Referring to FIG. 4b, a bit line contact hole (not shown) is formed by selectively etching the interlayer insulating layer 120 until the semiconductor substrate 100 forming the drain junction region is exposed. The polysilicon layer is filled in the bit line contact hole (not shown), and then planarized until the interlayer insulating layer 120 is exposed. While a conventional bit line contact is formed on both the source junction region and drain junction region, the bit line contact according to the present embodiment is formed only on one of them, e.g., the drain junction region.

A metal layer for the bit line electrode and a hard mask film are formed on the interlayer insulating layer 120 and the bit line contact plug 130. The metal layer and the hard mask film are selectively etched using an exposure mask defining the bit line, so that the stacked structure of the bit line electrode 142 and the bit line hard mask pattern 144 is formed. A nitride film for the spacer (not shown) is formed on the whole space including the stack pattern of the bit line electrode 142 and the bit line hard mask pattern 144, and then an etch-back process is performed so that the spacer 146 is formed on the side wall of the stack pattern of the bit line electrode 142 and the bit line hard mask pattern 144. The bit line 140 is formed to be electrically connected to the bit line contact plug 130 which is electrically coupled with the first source/drain region. However, the bit line contact plug 130 is not formed in the second source/drain region. Then, the second interlayer insulating layer 150 is formed on the bit line 140 and the first interlayer insulating layer 120.

Referring to FIG. 4c, until the source junction region of the sense amplifier transistor is exposed, the interlayer insulating layers 150, 120 are selectively dry-etched to form a metal plug contact hole (not shown). A SAC (Self Align Contact) etching method is applied using the etching selectivity between the nitride film used as a bit line hard mask film 144 for the insulation of the bit line electrode 142 and the nitride film used as a spacer 146.

Then, an amorphous metal film (not shown) is formed on the inner surface of the metal plug contact hole. Titanium Ti, titanium nitride TiN, cobalt Co or the alloy of these metals can be used as the amorphous metal film.

A thermal process is performed for the amorphous metal film so that the metal layer on the bottom of the metal plug contact hole can be transformed into a silicide film.

Alternatively, for example, the thermal process can be performed after removing the amorphous metal film from all other regions except the bottom of the metal plug contact hole. The thermal process can be performed at a temperature of 850 to 900 in the atmosphere of nitrogen N2.

The silicide film can lower the contact resistance between the source junction region and the metal plug which is supposed to be formed in a subsequent process.

Then, a plug layer (not shown) is filled into the metal plug contact hole. The plug layer can be formed of tungsten W, aluminum Al, copper Cu or an alloy of those metals. The metal plug 160 is formed by planarizing the plug layer until the interlayer insulating layer 150 is exposed using CMP or a dry etch back method. In the present embodiment, as described above, since the metal plug contact hole is formed by using the SAC etching method, the upper portion of the metal plug 160 is formed sufficiently broad so that the overlap margin between the metal plug 160 and the metal line contact plug 180 which is supposed to be formed in a subsequent process can be sufficiently secured.

Referring to FIG. 4d, after forming the interlayer insulating layer 170 on the interlayer insulating layer 150 and the metal plug 160, a metal line contact hole (not shown) is formed by selectively etching the interlayer insulating layer 170 using a metal line contact mask until the metal plug 160 is exposed.

After conductive material is filled in the metal line contact hole it is planarized to form the metal line contact plug 180. Then, the metal layer is formed on the interlayer insulating layer 170 and patterned to form a metal line 190.

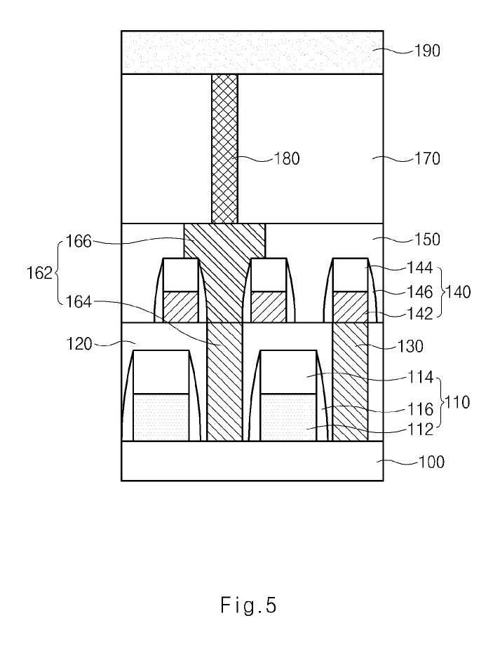

FIG. 5 is a cross-sectional diagram illustrating a configuration of a semiconductor device according to a second embodiment of the present invention.

In the semiconductor device of FIG. 5, the configuration of the metal plug is different in comparison with the semiconductor device of FIG. 3. The gap between bit lines becomes narrow as a semiconductor device is highly integrated. Therefore, it becomes difficult to etch interlayer insulating layers 120, 150 in one step to form the metal plug 160 as described in the first embodiment. Therefore, in the second embodiment, the metal plug is formed by two steps.

That is, the metal plug 160 of FIG. 3 is formed of a single layer. However, the metal plug 162 of FIG. 5 is formed of a bilayer in which the first metal plug 164 and the second metal plug 166 are stacked. The first metal plug 164 can be formed at the time when the bit line contact 130 is formed and the second plug 164 can be formed of the same material as the metal plug 160 of FIG. 3.

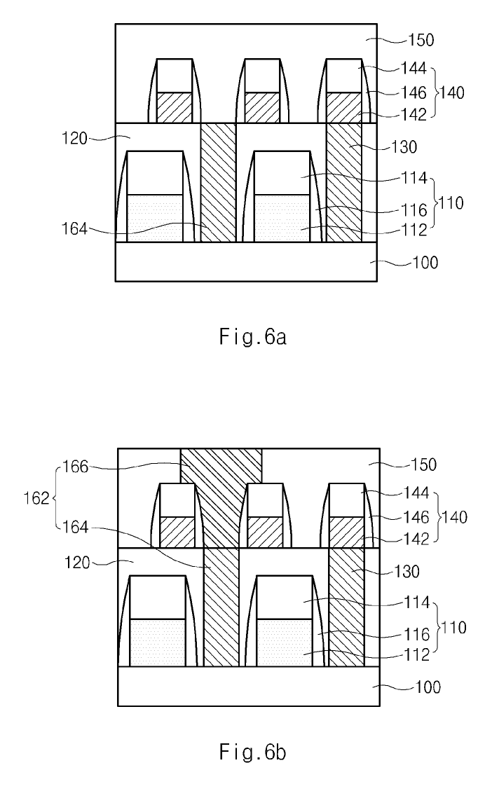

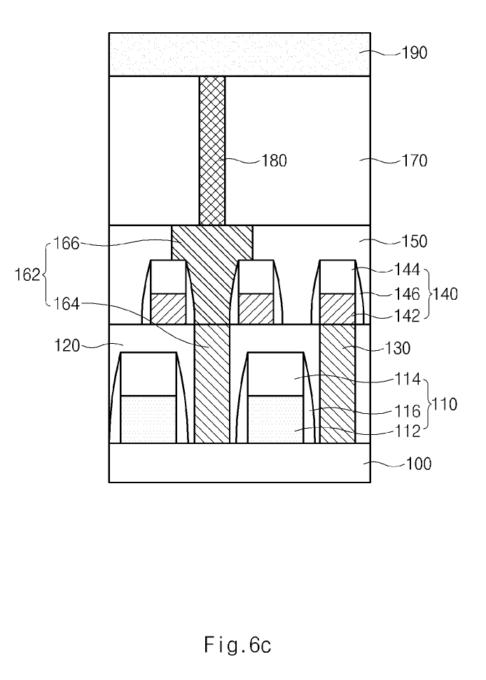

FIGS. 6a to 6c are cross-sectional diagrams for illustrating a manufacturing method of a semiconductor device shown in FIG. 5.

In FIG. 6a, an interlayer insulating layer 120 is formed in the same way as described in FIG. 4. When the interlayer insulating layer 120 is formed, the interlayer insulating layer 120 is selectively etched until the semiconductor substrate 100 for forming the source junction region and the drain junction region is exposed, so that a bit line contact hole (not shown) is formed. That is, according to the first embodiment, the bit line contact hole is formed only in the drain junction region, but in the second embodiment, the bit line contact hole is also formed in the source junction region.

Then, a polysilicon layer is filled in the bit line contact hole, and forms the bit line contact 130 and the first metal plug 164 by using a planarizing etch process until the interlayer insulating layer 120 is exposed. The bit line 140 and the interlayer insulating layer 150 are formed in the same way as described in the above first embodiment.

Referring to FIG. 6b, the interlayer insulating layer 150 is selectively etched until the first metal plug 164 is exposed to form the metal plug contact hole (not shown). The SAC (Self Align Contact) etching method is applied using the etching selectivity between the nitride film used as a bit line hard mask film 144 for the insulation of the bit line electrode 142 and the nitride film used as the spacer 146.

Then, a plug layer (not shown) is filled into the metal plug contact hole. The plug layer can be formed of tungsten (W), aluminum (Al), copper (Cu), or an alloy of these metals.

A second metal plug 166 is formed by planarizing the plug layer until the interlayer insulating layer 150 is exposed by CMP or a dry etch back method. In the second embodiment, as described above, since the metal plug contact hole is formed by using the SAC etching method, the upper portion of the second metal plug 166 is formed sufficiently broad so that the overlap margin between the second metal plug and the metal line contact plug 180 can be sufficiently secured in a subsequent process.

Referring to FIG. 6c, after forming an interlayer insulating layer 170 on the interlayer insulating layer 150 and the second metal plug 166, a metal line contact hole (not shown) is formed by selectively etching the interlayer insulating layer 170 until the second metal plug 166 is exposed.

After conductive material is filled into the metal line contact hole, the conductive material is planarized to form a metal line contact 180. Then, a metal layer is formed on the interlayer insulating layer 170 to form a metal line 190.

The above-described embodiment is one embodiment of the present invention, but the present invention is not limitative.

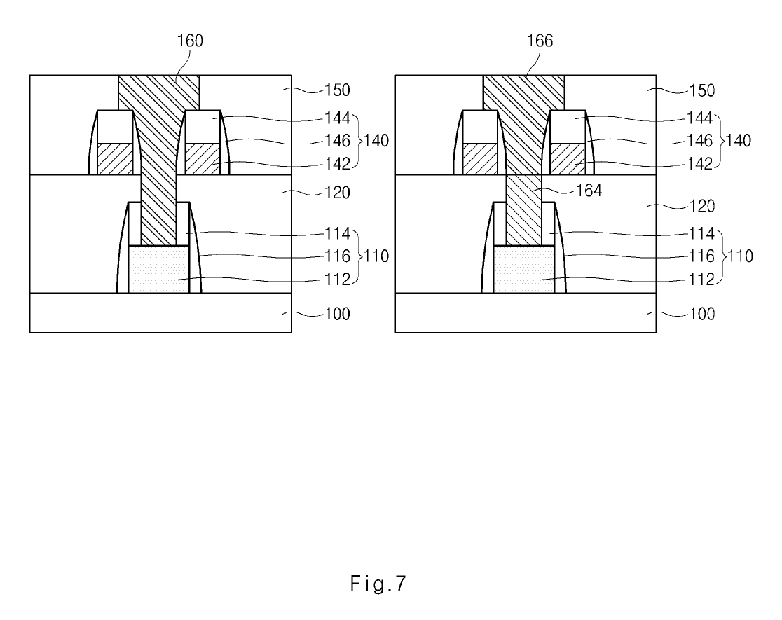

For example, even though the metal plug 160 or the first metal plug 164 is formed to be coupled with the source region of a transistor according to the first or the second embodiment, it can be coupled with a gate electrode 112 of a transistor, as shown in FIG. 7. That is, the metal plug 160 or the first metal plug 164 can be formed by forming the metal plug contact hole exposing the gate electrode 112 on the gate 110 of transistor and filling it with conductive material.

Moreover, in the above-described embodiment, since bit line patterns are irregular in shape and size in a core region and in a peripheral region as well, the present invention is applicable not only to a core region, but also to a peripheral region.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a gate formed on a semiconductor substrate;
a first junction region formed on a first side of the gate and a second junction region formed on a second side of the gate;
a bit line formed over the gate to be electrically coupled with the first junction region;
a first metal plug formed electrically coupling the second junction region;
a bit line contact plug provided between the first junction region and the bit line and electrically coupling the first junction region and the bit line; and
a second metal plug over the first metal plug and electrically coupling the first metal plug.

2. The semiconductor device according to claim 1, wherein the gate is formed in a core area or a peripheral area of the substrate.

3. The semiconductor device according to claim 1, wherein the second junction region is a source junction region or the gate.

4. The semiconductor device according to claim 1, wherein an upper portion of the first metal plug overlaps with at least a portion of the bit line.

5. The semiconductor device according to claim 1, wherein the second metal plug is formed between two neighboring bit lines and between the first metal plug and a metal line.

6. The semiconductor device according to claim 1, wherein the bit line has a substantially uniform width.

7. The semiconductor device according to claim 1, wherein the first metal plug includes tungsten (W), aluminum (Al), copper (Cu), or an alloy thereof.

8. The semiconductor device according to claim 1, wherein the first and second metals plug include different materials from each other, and
wherein the second metal plug is a metal line contact plug.

9. The semiconductor device according to claim 8, wherein the first metal plug and the bit line contact include the same material.

10. The semiconductor device according to claim 9, wherein the second metal plug—includes tungsten (W), aluminum (Al), copper (Cu), or an alloy thereof.

11. The semiconductor device according to claim 1, further comprising:
a silicide film formed between the first metal plug and the second junction region.

12. The semiconductor device according to claim 1, wherein an upper portion of the first metal plug has a larger cross-sectional dimension than a lower portion of the first metal plug 13. A method of manufacturing a semiconductor device, the method comprising:
providing a substrate having a gate and first and second junction regions on first and second sides, respective, of the gate;
forming a first insulating layer over the gate;
forming a bit line contact plug to electrically couple the first junction region;
forming a first metal plug to electrically couple the second junction region, the first metal plug extending through the first insulating layer;
forming a bit line over the first junction region to electrically couple the bit line contact plug;
forming a second insulating layer over the first insulating layer and the bit line; and
forming a second metal plug to electrically couple the first metal plug, the second metal plug extending through the second insulating layer.

14. The method according to claim 13, wherein forming the first metal plug comprises:
forming a contact hole through the first insulating layer to expose the second junction region;
forming a metal layer to fill in the contact hole; and
forming a silicide film at an interface between the metal layer and the second junction region.

15. The method according to claim 13, further comprising:
forming a metal line over the second insulating layer and the second metal plug, the second metal plug being a metal line contact plug that electrically couples the metal line and the first metal plug.

16. The method according to claim 14, wherein the contact hole is formed using a Self Align Contact etching method.

17. The method according to claim 13, wherein
the first metal plug and the second metal plug include the same material.

18. The method according to claim 13, wherein
the first metal plug and the second metal plug include different materials.

19. The method according to claim 13,
wherein an upper portion of the first metal plug has a larger cross-sectional dimension than a lower portion of the first metal plug.

20. The method according to claim 13, wherein, the bit line has a substantially uniform width.
